(19) United States
(12) Patent Application Publication
(10) Pub. No.: US 2014/0057123 A1
(43) Pub. Date: Feb. 27, 2014

(54) COPPER FOIL FOR PRINTED CIRCUIT

(71) Applicants: Hideta Arai, Ibaraki (JP); Atsushi Miki, Ibaraki (JP)

(72) Inventors: Hideta Arai, Ibaraki (JP); Atsushi Miki, Ibaraki (JP)

(73) Assignee: JX NIPPON MINING & METALS CORPORATION, Tokyo (JP)

(21) Appl. No.: 14/006,140

(22) PCT Filed: Feb. 10, 2012
(86) PCT No.: PCT/JP2012/053107

§ 371 Date: Oct. 13, 2013

(30) Foreign Application Priority Data
Mar. 30, 2011 (JP) 2011-074590

(51) Int. Cl. H05K 1/09

(52) U.S. Cl. CPC H05K 1/09
USPC 428/551; 428/607; 428/555

(57) ABSTRACT

Provided is a copper foil with surface treated layers, wherein a copper foil or a copper alloy foil includes a plurality of surface treated layers configured from a roughened layer formed on the copper foil or the copper alloy foil by roughening treatment, a heat-resistant layer made from a Ni—Co layer formed on the roughened layer, and a weathering layer and a rust-preventive layer which contain Zn, Ni, and Cr and is formed on the heat-resistant layer, and the surface treated layers having a (total Zn)/[(total Zn)+(total Ni)] ratio of 0.13 or more and 0.23 or less. In a copper foil clad laminate which uses a copper foil for a printed circuit obtained by performing roughening treatment on a surface of a copper foil and then forming a heat-resistant layer and a rust-preventive layer thereon, and to which silane coupling treatment is subsequently performed, the copper foil for a printed circuit can further inhibit the deterioration in adhesion caused by the acid infiltration into the interface of the copper foil circuit and the substrate resin upon performing acid treatment or chemical etching to the substrate after forming a fine-pattern printed circuit. Thus, the copper foil for printed circuit has superior acid-resistant adhesive strength and superior alkali etchability.

### TECHNICAL FIELD

The present invention relates to a copper foil for a printed circuit and a copper clad laminate, and, in a copper clad laminate which uses a copper foil for a printed circuit obtained by performing roughening treatment on a surface of a copper foil and then forming a heat-resistant layer, a weathering layer and a rust-preventive layer thereon, and to which silane coupling treatment is subsequently performed. The present invention particularly relates to a copper foil for a printed circuit which can further inhibit the deterioration in adhesion caused by the acid “infiltration” into the interface of the copper foil circuit and the substrate resin upon performing acid treatment or chemical etching to the substrate after forming a fine-pattern printed circuit. Thus, the copper foil for printed circuit has superior acid-resistant adhesive strength and superior alkali etchability.

The copper foil for a printed circuit of the present invention is suitable for a flexible printed circuit (FPC) and a fine-pattern printed circuit.

### BACKGROUND ART

A copper and a copper alloy foil (collectively referred to as “copper foil”) are contributing significantly to the development of the electric/electronic-related industries; in particular, they are essential as printed circuit materials. A copper foil for a printed circuit is generally manufactured by foremost producing a copper clad laminate by laminating and bonding a copper foil on a base material such as a synthetic resin board or a polyimide film via an adhesive, or under high temperature and high pressure without using an adhesive, or by applying, drying and solidifying a polyimide precursor. Subsequently, in order to form the intended circuit, after printing the intended circuit by way of resist application and the exposure process, the unwanted portions are eliminated via the etching process

Finally, the required elements are soldered to form various printed circuit boards for use in electronic devices. A copper foil for a printed circuit board is formed differently with its surface (roughened surface) to be bonded with the resin base material, and a non-bonding surface (glossy surface); and for the respective surfaces, many methods have been proposed.

The roughened surface formed on the copper foil is mainly demanded of the following, for example: 1) no oxidative discoloration during storage, 2) peel strength from the base material is sufficient even after high-temperature heating, wet processing, soldering, chemical treatment and the like, and 3) there is no so-called layer contamination that arises after the lamination with the base material and the etching process.

The roughening treatment of the copper foil plays an important role as the factor that decides the adhesion between the copper foil and the base material. As this roughening treatment, the copper roughening treatment of electrodepositing copper was initially adopted, but various techniques have been proposed thereafter. The copper-nickel roughening treatment has been established as one of the representative treatment methods aiming to improve the heat-resistant peel strength, hydrochloric acid resistance, and oxidation resistance.

The present applicant proposed the copper-nickel roughening treatment (refer to Patent Document 1), and performed adequately. The copper-nickel treated surface takes on a black color and particularly with a rolled foil for use in a flexible substrate, the black color of this copper-nickel treatment is now acknowledged as the symbol of the product.

Nevertheless, while the copper-nickel roughening treatment is superior in terms of heat-resistant peel strength, oxidation resistance and hydrochloric acid resistance, it is difficult to perform etching with an alkali etching solution, which is now important for use in the treatment of fine patterns, and the treated layer contains etching residues during the formation of fine patterns having a circuit width of a 150 μm pitch or less.

Thus, for the treatment of fine patterns, the present applicant previously developed Cu—Co treatment (refer to Patent Document 2 and Patent Document 3) and Cu—Co—Ni treatment (refer to Patent Document 4).

While these roughening treatments were favorable in terms of etching properties, alkali etching properties and hydrochloric acid resistance, it came to appear that the heat-resistant peel strength deteriorates when an acrylic adhesive is used; and the color was also brown to dark brown, and did not reach the level of black.

In response to the foregoing demands, the present applicant succeeded in developing a copper foil treatment method of forming a cobalt plated layer or a cobalt-nickel alloy plated layer on the surface of a copper foil after performing roughening treatment based on copper-cobalt-nickel alloy plating. By this method, in addition to comprising many of the general characteristics of the copper foil for a printed circuit described above, it became possible to comprise the various characteristics described above which are comparable to Cu—Ni treatment. It further enabled to yield the effects of preventing the deterioration in the heat-resistant peel strength upon using an acrylic adhesive, realizing superior oxidation resistance properties, and achieving a black colored surface (refer to Patent Document 5).

Since demands for higher heat-resistant peel strength are becoming severe in the course of further advancement of electronic devices, the present applicant succeeded in developing a treatment method of a copper foil for printing having superior heat resistance properties, whereby the copper foil is obtained by forming a cobalt-nickel alloy plated layer on the surface of a copper foil after performing roughening treatment based on copper-cobalt-nickel alloy plating, and thereafter additionally forming a zinc-nickel alloy plated layer (refer to Patent Document 6). This is an extremely effective invention, and has become one of today's main products as a copper foil circuit material.

Subsequently, the downsizing and higher integration of semiconductor devices have further advanced in the course of further advancement of electronic devices, and the multilayered substrate technology of FPC has developed rapidly. In the production process of this FPC multilayered substrate, after forming a fine pattern circuit with a copper clad laminate, a surface etching process is performed a plurality of times using an etching solution containing sulfuric acid and hydrogen peroxide or a solution using a sulfuric acid aqueous solution as the pretreatment for cleaning the copper foil circuit substrate in the resist film contact bonding process or the metal plating process.

However, with the surface etching process in the FPC multilayered substrate production process described above, a problem arose; namely, in the fine pattern circuit of a copper clad laminate using a copper foil for printing obtained by performing roughening treatment, based on copper-cobalt-nickel alloy plating, on the surface of a copper foil, thereafter forming a cobalt-nickel alloy plated layer, and thereafter forming a zinc-nickel alloy plated layer as described in Patent Document 6, the surface etching solution had infiltrated into the interface of the copper foil circuit and the substrate resin. The infiltration caused deterioration of the adhesion between the copper foil circuit and the substrate resin, and an electronic circuit failure would occur as the FPC characteristics. Thus, there are demands for resolving the problem.

In Patent Document 7 below, the present applicant proposed a technique of establishing the total amount of the zinc-nickel alloy plated layer, the nickel content, and the nickel ratio in a copper foil for a printed circuit obtained by forming a roughened layer; which was realized by copper-cobalt-nickel alloy plating, on the surface of a copper foil, forming a cobalt-nickel alloy plated layer on the roughened layer, and forming a zinc-nickel alloy plated layer on the cobalt-nickel alloy plated layer.

While this technique is effective, since Ni can be included in the roughened layer, the heat-resistant layer, and the weathering layer in addition to the zinc-nickel alloy layer, it was found that further examination is required pursuant to the total Ni content in the roughened layer, the heat-resistant layer, and the weathering layer in order to obtain a copper foil for a printed circuit capable of yielding extremely superior effects in terms of circuit corrosion prevention in surface etching as well as in general FPC properties.

Further, since Zn can be included in the weathering layer and the rust-preventive layer in addition to the zinc-nickel alloy layer, it was found that further examination is required pursuant to the total Zn content in the weathering layer and the rust-preventive layer as well as of the ratio thereof relative to the foregoing total Ni content.

### PRIOR ART DOCUMENTS

Patent Document 1: JP-A-S52-145769
Patent Document 2: Japanese Examined Patent Application Publication No. S63-2158
Patent Document 3: JP-A-H2-292895
Patent Document 4: JP-A-H2-292894
Patent Document 5: Japanese Examined Patent Application Publication No. H6-54831
Patent Document 6: Japanese Examined Patent Application Publication No. H9-87889
Patent Document 7: WO2009/041292

### SUMMARY OF THE INVENTION

### Problems to be Solved by the Invention

The present invention relates to a copper foil for a printed circuit and a copper clad laminate, and, in a copper clad laminate which uses a copper foil for a printed circuit obtained by performing roughening treatment on a surface of a copper foil and then forming a heat-resistant layer and a rust-preventive layer thereon, and to which silane coupling treatment is subsequently performed, the present invention particularly relates to a copper foil for a printed circuit which can further inhibit the deterioration in adhesion caused by the acid “infiltration” into the interface of the copper foil circuit and the substrate resin upon performing acid treatment or chemical etching to the substrate after forming a fine-pattern printed circuit, and yield superior acid-resistant adhesive strength and superior alkali etchability.

While the downsizing and higher integration of semiconductor devices are further advancing and even stricter demands are being made to the production process of the printed circuits thereof in the course of further advancement of electronic devices, an object of the present invention is to provide useful technology that can meet the foregoing demands.

### Means for Solving the Problems

In light of the above, the present application provides the following invention.

1) A copper foil with surface treated layers, wherein a copper foil or a copper alloy foil includes a plurality of surface treated layers configured from a roughened layer formed on the copper foil or the copper alloy foil by roughening treatment, a heat-resistant layer made from a Ni—Co layer formed on the roughened layer, and a weathering layer and a rust-preventive layer which contain Zn, Ni, and Cr and is formed on the heat-resistant layer, and the surface treated layers have a (total Zn content)/[(total Zn content)+(total Ni content)] ratio of 0.13 or more and 0.23 or less.

2) The copper foil with surface treated layers according to 1) above, wherein a total Ni content in the surface treated layers is 450 to 1100 μg/dm².

3) The copper foil with surface treated layers according to 1) or 2) above, wherein a total Co content in the surface treated layers is 770 to 2500 μg/dm², and a (total Co)/[(total Zn+total Ni)] ratio is 3.0 or less.

4) The copper foil with surface treated layers according to any one of 1) to 3) above, wherein a total Cr content in the surface treated layers is 50 to 130 μg/dm².

The present application additionally provides the following invention.

5) The copper foil with surface treated layers according to any one of 1) to 4) above, wherein a Ni content in the roughened layer is 50 to 550 μg/dm².

6) The copper foil with surface treated layers according to any one of 1) to 5) above, wherein the roughened layer is a layer roughened made from elements of Co, Cu, and Ni.

7) The copper foil with surface treated layers according to any one of 1) to 5) above, wherein the roughened layer is made from fine particles of a ternary alloy of Cu, Co, and Ni having an average particle size of 0.05 to 0.60 μm.

8) The copper foil with surface treated layers according to any one of 1) to 5) above, wherein the roughened layer is configured from a primary particle layer made of Cu having an average particle size of 0.25 to 0.45 μm, and a secondary particle layer made from a ternary alloy of Cu, Co, and Ni having an average particle size of 0.05 to 0.25 μm formed on the primary particle layer.

9) A copper foil for a printed circuit made from the copper foil with surface treated layers according to any one of 1) to 8) above.

10) A copper clad laminate obtained by laminating and bonding the copper foil for a printed circuit according to 9) above to a resin substrate.

### Effect of the Invention

The present invention relates to a copper foil with surface treated layers for use in a copper foil for a printed circuit and a copper clad laminate, and, in a copper clad laminate which uses a copper foil for a printed circuit obtained by performing roughening treatment on a surface of a copper foil and then forming a heat-resistant layer and a rust-preventive layer thereon, and to which silane coupling treatment is subsequently performed, the present invention particularly relates to a copper foil for a printed circuit which can further inhibit the deterioration in adhesion caused by the acid “infiltration” into the interface of the copper foil circuit and the substrate resin upon performing acid treatment or chemical etching to the substrate after forming a fine-pattern printed circuit, and yield superior acid-resistant adhesive strength and superior alkali etchability.

While the downsizing and higher integration of semiconductor devices are further advancing and even stricter demands are being made to the production process of the printed circuits thereof in the course of further advancement of electronic devices, the present invention can provide useful technology that can meet the foregoing demands.

### BRIEF DESCRIPTION OF THE INVENTION

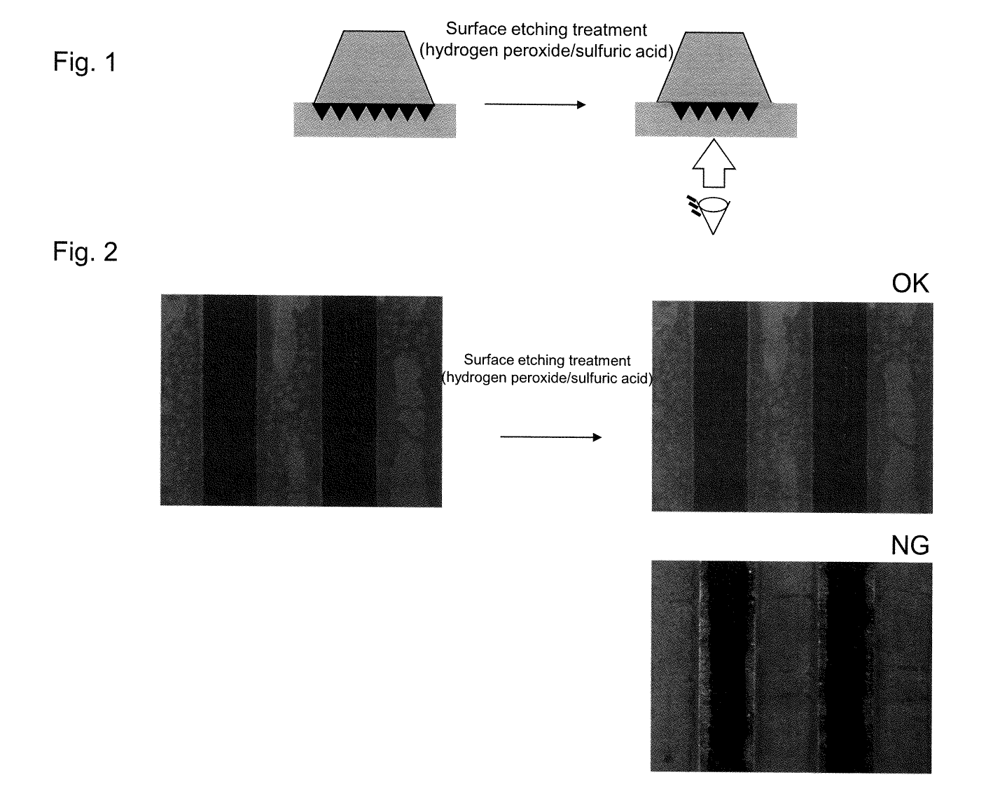

FIG. 1 is an explanatory diagram showing a state where the etching solution is eroding the copper foil circuit from its periphery in a case of performing surface etching using a solution of hydrogen peroxide and sulfuric acid.

FIG. 2 is a diagram (photograph) showing the results upon observing the “infiltration” of the etching solution into the interface of the copper foil circuit and the substrate resin in a case of performing surface etching (based on a solution of hydrogen peroxide and sulfuric acid) to the substrate after forming a fine-pattern printed circuit. The upper diagram (photograph) shows a case with no “infiltration”, and the lower diagram (photograph) shows a case with “infiltration”.

### BEST MODE FOR CARRYING OUT THE INVENTION

The main objective of the present invention is to prevent the circuit corrosion that occurs in the surface etching performed during the pretreatment in the production process of an FPC multilayered substrate.

With the copper foil with surface treated layers of the present invention, a copper foil or a copper alloy foil includes a plurality of surface treated layers configured from a roughened layer formed on the copper foil or the copper alloy foil by roughening treatment, a heat-resistant layer made from a Ni—Co layer formed on the roughened layer, and a weathering layer and a rust-preventive layer which contain Zn, Ni, and Cr and is formed on the heat-resistant layer; and the surface treated layers have a (total Zn content)/[(total Zn content)+(total Ni content)] ratio of 0.13 or more and 0.23 or less.

The foregoing is the primary condition for effectively preventing the “infiltration” which occurs during surface etching.

Zn is a constituent of the weathering layer and the rust-preventive layer in the surface treated layers of the copper foil, Ni is a constituent of the roughened layer, the heat-resistant layer, and the weathering layer, and Zn and Ni are important constituents of the surface treated layers of the copper foil.

Nevertheless, while Zn is a component that is effective in terms of weatherability, it is also an undesirable component in terms of chemical resistance during the fine pattern circuit forming process, and “infiltration” tends to occur during the etching process for forming a circuit.

While Ni is a component that is effective in preventing “infiltration”, however, if the amount of Ni is excessive, it will cause the alkali etchability to deteriorate, which will be inadequate for use in a printed circuit.

Thus, the present invention discovered the importance of balance between Zn and Ni. In other words, a (total Zn content)/[(total Zn content)+(total Ni content)] ratio in the surface treated layers is 0.13 or more and 0.23 or less.

When the foregoing ratio is less than 0.13, where are cases where the Zn is too little or the Ni is too much, and in the case where the Zn is too little, the weatherability will deteriorate and, in the case where the Ni is too much, the etchability becomes a problem, and neither case is desirable. Meanwhile, when the foregoing ratio exceeds 0.23, the acid resistance will deteriorate, and this is undesirable since “infiltration” tends to occur during etching.

Note that the definition of “total Zn content” would be “total amount of Zn contained in the roughened layer, the heat-resistant layer, the weathering layer, and the rust-preventive layer on the copper foil”, but the total Zn content would be the amount of Zn contained in two layers, namely, the weathering layer and the rust-preventive layer since Zn is not normally contained in the roughened layer and the heat-resistant layer. Similarly, since Ni is not normally contained in the rust-preventive layer, the definition of “total Ni content” would be “total amount of Ni contained in the roughened layer, the heat-resistant layer, the weathering layer, and the rust-preventive layer on the copper foil”, but the total Ni content would be the amount of Ni contained in the roughened layer, the heat-resistant layer, and the weathering layer.

The term “infiltration” as used herein is, as shown in FIG. 1, a phenomenon of the etching solution infiltrating the interface of the copper foil and the resin in cases of performing surface etching using a solution of hydrogen peroxide and sulfuric acid, or performing etching to form a circuit by using an etching solution made from a cupric chloride solution, a ferric chloride solution or the like. The left side of FIG. 1 is a conceptual diagram showing the state (▾ part) where the resin layer and the circuit surface of the copper foil with surface treated layers are bonded closely together. The right side of FIG. 1 is a conceptual diagram showing the state (▾ part) where infiltration has occurred at both edges of the circuit, and the adhesion is deteriorating.

Moreover, FIG. 2 is a diagram (photograph) showing the results upon observing the “infiltration” of the etching solution into the interface of the copper foil circuit and the substrate resin in a case of performing soft etching (based on a solution of hydrogen peroxide and sulfuric acid) to the substrate after forming a fine-pattern printed circuit. The upper diagram (photograph) shows a case with no infiltration at the edges of a linear circuit, and the lower diagram (photograph) shows a case with “infiltration”. Disturbance at the edges of the linear circuit can be observed.

As described above, Ni is a component that is included in the roughened layer, the heat-resistant layer, the weathering layer, and the rust-preventive layer of the surface treated layers, and is an extremely important component in the surface treated layers of the copper foil. In addition, Ni is a component that is effective in preventing “infiltration”, which is a problem to be solved by the present invention.

Thus, with the copper foil with surface treated layers in the present invention, the total Ni content in the surface treated layers is desirably 450 to 1100 μg/dm².

Moreover, with the Ni contained in the roughened layer, since the surface of the surface treated copper foil needs to appear black, Ni needs to be contained in an amount of 50 μg/dm² or more.

In addition, since Ni is also contained in the heat-resistant layer and the weathering layer, the total Ni content needs to be 450 μg/dm² or more. However, when the total Ni content exceeds 1100 μg/dm², problems such as the alkali etchability deteriorating and the roughened particles remaining on the substrate resin surface during the circuit etching will arise, and it could be said that the Ni content is desirably 1100 μg/dm² or less.

In addition, Co is an important component that contributes to heat resistance as a component that is used in the surface treated layers of the copper foil, and is used in a greater amount than the other components. Nevertheless, Co is also an undesirable component in terms of “infiltration”. Thus, with the copper foil with surface treated layers of the present invention, the total Co content in the surface treated layers is desirably 770 to 2500 μg/dm².

Meanwhile, if the Co content is less than 770 μg/dm², sufficient heat resistant properties cannot be obtained, and if the Co content exceeds 2500 μg/dm², considerable “infiltration” will occur, and the Co content needs to be within the foregoing range. And, a (total Co content)/[(total Zn content)+(total Ni content)] ratio is preferably 3.0 or less. This is because, even when the total Co content is within the foregoing range, if the total Co content is great relative to the sum of the total Zn content and the total Ni content as the other main components, “infiltration” tends to aggravate.

Moreover, with the copper foil with surface treated layers of the present invention, the total Cr content in the surface treated layers is desirably 50 to 120 μg/dm². The Cr content in the foregoing range similarly yields the effect of inhibiting the amount of infiltration.

Moreover, the Ni content in the roughened layer of the copper foil with surface treated layers of the present invention is effective at 50 to 550 μg/dm².

Moreover, with regard to the roughened layer, a roughened layer made from elements of Co, Cu and Ni is effective. The roughened layer can also be made from an assembly of fine particles of a ternary alloy of Cu, Co and Ni having an average particle size of 0.05 to 0.60 μm.

The roughened layer can also be configured from a primary particle layer made of Cu having an average particle size of 0.25 to 0.45 μm, and a secondary particle layer made from a ternary alloy of Cu, Co and Ni having an average particle size of 0.05 to 0.25 μm formed on the primary particle layer.

As the conditions for forming the roughened layer, the heat resistance layer made from a Ni—Co layer, and the weathering layer and the rust-preventive layer which contain Zn, Ni and Cr, the following electroplating conditions may be used.

### (Roughening Treatment Conditions)

When performing roughening treatment of a fine roughened particle assembly made of a ternary alloy of Cu, Co and Ni having an average particle size of 0.05 to 0.60 μm:

Liquid composition: Cu 10 to 20 g/liter, Co 1 to 10 g/liter, Ni 1 to 15 g/liter
pH: 1 to 4

### Temperature: 30 to 50° C.

Current density (Dk): 20 to 50 A/dm²
Time: 1 to 5 seconds

When performing roughening treatment of primary particle layer made of Cu having an average particle size of 0.25 to 0.45 μm, and a secondary particle layer made from a ternary alloy of Cu, Co and Ni having an average particle size of 0.05 to 0.25 μm formed on the primary particle layer:

### (A) Formation of Primary Particle Layer Made of Cu:

Liquid composition: Cu 10 to 20 g/liter, sulfuric acid 50 to 100 g/liter
pH: 1 to 3

### Temperature: 25 to 50° C.

Current density (Dk): 1 to 60 A/dm²
Time: 1 to 5 seconds
(B) Formation of Secondary Particle Layer Made from a Ternary Alloy of Cu, Co and Ni:
Liquid composition: Cu 10 to 20 g/liter, Co 1 to 15 g/liter, Ni 1 to 15 g/liter
pH: 1 to 3

### Temperature: 30 to 50° C.

Current density (Dk): 10 to 50 A/dm²
Time: 1 to 5 seconds

Moreover, prior to forming the foregoing primary particles, metal layer plating may be performed between the copper foil and the primary particles. As the metal plated layer, representative examples would be a copper plated layer or a copper alloy plated layer. When forming a copper plated layer, considered may be a method of using only a copper sulfate aqueous solution containing copper sulfate and sulfuric acid as the main components, or a method of forming the copper plated layer via electroplating by using a copper sulfate aqueous solution obtained by combining sulfuric acid, an organic sulfur compound having a mercapto group, an interface activator such as polyethylene glycol, and chloride ions.

### (Conditions for Forming Heat-Resistant Layer)

Liquid composition: Co 1 to 20 g/liter, N±1 to 20 g/liter
pH: 1 to 4

### Temperature: 30 to 60° C.

Current density (Dk): 1 to 20 A/dm²
Time: 1 to 5 seconds

### (Condition 1 for Forming Weathering Layer and Rust-Preventive Layer)

Liquid composition: N±1 to 30 g/liter, Zn 1 to 30 g/liter
pH: 2 to 5

### Temperature: 30 to 50° C.

Current density (Dk): 1 to 3 A/dm²
Time: 1 to 5 seconds
(Condition 2 for forming weathering layer and rust-preventive layer)
Liquid composition: K₂Cr₂O₇: 1 to 10 g/liter, Zn: 0 to 10 g/liter
pH: 2 to 5

### Temperature: 30 to 50° C.

Current density (Dk): 0.01 to 5 A/dm²
Time: 1 to 5 seconds

Immersion chromate treatment may be performed by setting the plating current density to 0 A/dm².

### (Silane Coupling Treatment)

Performed is silane coupling treatment of applying a silane coupling agent to at least the roughened surface on the rust-preventive layer.

As the silane coupling agent, olefin-based silane, epoxy-based silane, acryl-based silane, amino-based silane, and mercapto-based silane may be suitably selected and used.

The method of application may be any one of the following; for instance, spraying of the silane coupling agent solution, coater application, dipping, pouring or the like. Since these are publicly known technologies (for example, refer to Japanese Examined Patent Application Publication No. S60-15654), the detailed explanation thereof is omitted.

### EXAMPLES

The Examples (and Comparative Examples) are now explained. Note that these Examples are for facilitating the understanding of the present invention, and it should be easy to understand that the present invention is not limited by the following Examples, and the technical concept of this invention should be comprehended from the overall descriptions in this specification.

While a rolled copper foil of 18 μm was used in the Examples (and Comparative Examples), it should be easy to understand that any publicly known thickness of a copper foil may be applied to the thickness of the copper foil in the present invention.

### Common Items in Example 1 to Example 5

Roughening treatment was performed to a rolled copper foil of 18 μm under the following conditions.

### (A) Formation of Primary Particle Layer Made of Cu

Liquid composition: Cu 15 g/liter, sulfuric acid 75 g/liter
pH: 1 to 3

### Temperature: 35° C.

Current density (Dk): 40 to 60 A/dm²
Time: 0.05 to 3 seconds
(B) Formation of Secondary Particle Layer Made from a Ternary Alloy of Cu, Co and Ni:
Liquid composition: Cu 15 g/liter, Co 8 g/liter, Ni 8 g/liter
pH: 1 to 3

### Temperature: 40° C.

Current density (Dk): 20 to 40 A/dm²
Time: 0.05 to 3 seconds

In the foregoing roughening treatment, formed were a primary particle layer made of Cu having an average particle size of 0.25 to 0.45 μm, and a secondary particle layer made from a ternary alloy of Cu, Co and Ni having an average particle size of 0.05 to 0.25 μm formed on the primary particle layer.

The roughened particle size was evaluated by observing the roughened particles of the copper foil with the surface treated layers using a 30000× scanning electron microscope (SEM).

The Ni deposit at the roughening treatment stage was 50 to 250 μg/dm². These results are shown in Table 1 below.

### Conditions of Example 1

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 5 to 15 A/dm²
Time: 0.05 to 3.0 seconds

### 2) Weatherable Layer (Zn—Ni Layer)

Current density (Dk): 0.5 to 1.5 A/dm²
Time: 0.05 to 3.0 seconds

### 3) Rust-Preventive Layer (Cr—Zn Layer)

Current density (Dk): 1 to 3 A/dm²
Time: 0.05 to 3.0 seconds

Plate processing was performed so that the overall Ni deposit in the roughened layer, the heat-resistant layer and the weathering layer will be 1094 μg/dm². Based on the Zn deposit in the weathering layer and the rust-preventive layer, Zn/(Ni+Zn)=0.13.

Based on the Co deposit in the roughened layer and the heat-resistant layer, Co/(Ni+Zn)=1.6.

Polyamic acid (U Varnish A manufactured by Ube Industries) was applied on the surface treated copper foil produced as described above, and the surface treated copper foil was dried at 100° C. and hardened at 315° C. to form a copper clad laminated made from a polyimide resin substrate.

Subsequently, the obtained copper clad laminate was etched to form a fine pattern circuit by using a general copper chloride-hydrochloric acid etching solution. The obtained fine pattern circuit substrate was dipped for 5 minutes in an aqueous solution made from sulfuric acid 10 wt % and hydrogen peroxide 2 wt %, and the interface of the resin substrate and the copper foil circuit was thereafter observed using an optical microscope to evaluate the infiltration.

As a result of evaluating the infiltration, the infiltration width was favorable at ≦5 μm.

The foregoing surface treated copper foil was laminated and bonded to a glass cloth-based epoxy resin board, and, after measuring the normal (room temperature) peel strength (kg/cm), the sulfuric acid resistance degradation ratio was obtained by measuring the peel strength after dipping a 0.2 mm width circuit for 1 hour in an 18% hydrochloric acid aqueous solution.

The normal peel strength was 0.90 kg/cm, and the sulfuric acid resistance degradation was 10 (Loss %) or less, and both were favorable.

In order to check the alkali etchability, after preparing a sample obtained by covering the roughened surface of the foregoing surface treated copper foil with plastic tape, the sample was dipped for 7 minutes in an alkali etching solution made from NH₄OH: 6 mol/liter, NH₄CI: 5 mol/liter, CuCl₂·2H₂O: 2 mol/liter, and temperature 50° C., and the residual roughened particles on the plastic tape were confirmed.

As a result of evaluating alkali etching, residual roughened particles were not observed, and the alkali etchability was favorable (∘).

The foregoing results are shown in Table 1. In addition, the overall Cr deposit was 89 μg/dm², the overall Co deposit was 2034 μg/dm², and the overall Zn deposit was 165 μg/dm².

Note that the measurement of the respective metal deposits described above was performed by dissolving the treatment surface of the copper foil with surface treated layers, and evaluating the metal deposits via atomic absorption spectrometry (AA240FS manufactured by VARIAN).

TABLE 1

| | | Ni deposit | | | | | | Sulfuric acid |
|---|---|---|---|---|---|---|---|---|
| | Ni deposit | (roughening | | | Peel | Infiltration | | resistance |
| | (overall) | stage) | | | strength | width | Alkali | degradation |
| | (μg/dm²) | (μg/dm²) | Zn/(Ni + Zn) | Co/(Ni + Zn) | (kg/cm) | (μm) | etchability | (Loss %) |
| Example 1 | 1094 | 50 to 250 | 0.13 | 1.6 | 0.90 | ≦5 (◯) | ◯ | ≦10 (◯) |
| Example 2 | 453 | 50 to 250 | 0.18 | 2.7 | 0.91 | ≦5 (◯) | ◯ | 11 (◯) |
| Example 3 | 683 | 50 to 250 | 0.19 | 2.1 | 0.90 | ≦5 (◯) | ◯ | 25 (◯) |
| Example 4 | 758 | 50 to 250 | 0.23 | 1.8 | 0.90 | 0 (◯) | ◯ | 22 (◯) |
| Example 5 | 815 | 50 to 250 | 0.22 | 1.8 | 0.90 | 0 (◯) | ◯ | 12 (◯) |
| Example 6 | 1093 | 200 to 400 | 0.18 | 1.9 | 0.88 | 0 (◯) | ◯ | ≦10 (◯) |
| Example 7 | 790 | 300 to 550 | 0.22 | 2.2 | 0.85 | 0 (◯) | ◯ | ≦10 (◯) |
| Comparative | 1197 | 50 to 250 | 0.06 | 1.7 | 0.89 | >5 (X) | X | ≦10 (◯) |
| Example 1 | | | | | | | | |
| Comparative | 1237 | 50 to 250 | 0.10 | 1.5 | 0.90 | ≦5 (◯) | X | ≦10 (◯) |
| Example 2 | | | | | | | | |
| Comparative | 311 | 50 to 250 | 0.25 | 2.9 | 0.88 | ≦5 (◯) | ◯ | 35 (X) |
| Example 3 | | | | | | | | |
| Comparative | 599 | 50 to 250 | 0.38 | 1.6 | 0.90 | 0 (◯) | ◯ | 40 (X) |
| Example 4 | | | | | | | | |
| Comparative | 816 | 200 to 400 | 0.13 | 3.2 | 0.90 | >5 (X) | ◯ | ≦10 (◯) |
| Example 5 | | | | | | | | |

### Example 2

The Ni deposit at the roughening stage was, as described above, 50 to 250 μg/dm². Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 5 to 9 A/dm²
Time: 0.05 to 3.0 seconds

### 2) Weatherable Layer (Zn—Ni Layer)

Current density (Dk): 0.05 to 0.7 A/dm²
Time: 0.05 to 3.0 seconds

### 3) Rust-Preventive Layer (Cr—Zn Layer)

Current density (Dk): 1 to 3 A/dm²
Time: 0.05 to 3.0 seconds

The overall Ni deposit in the roughened layer, the heat-resistant layer and the weathering layer was 453 μg/dm², based on the Zn deposit in the weathering layer and the rust-preventive layer, Zn/(Ni+Zn)=0.18, and based on the Co deposit in the roughened layer and the heat-resistant layer, Co/(Ni+Zn)=2.7. As a result of evaluating the infiltration, the infiltration width was favorable at 55 μm.

As a result of evaluating the adhesive strength, the normal peel strength was 0.91 kg/cm, and the sulfuric acid resistance degradation was 11 (Loss %), and the adhesive strength was favorable. No residual particles were observed in the evaluation of alkali etching, and the results were favorable (∘).

The foregoing results are shown in Table 1. In addition, the overall Cr deposit was 84 μg/dm², the overall Co deposit was 1494 μg/dm², and the overall Zn deposit was 100 μg/dm².

### Example 3

The Ni deposit at the roughening stage was, as described above, 50 to 250 μg/dm². Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 6 to 11 A/dm²
Time: 0.05 to 3.0 seconds

### 2) Weatherable Layer (Zn—Ni Layer)

Current density (Dk): 0.05 to 0.7 A/dm²
Time: 0.05 to 3.0 seconds

### 3) Rust-Preventive Layer (Cr—Zn Layer)

Current density (Dk): 2 to 4 A/dm²
Time: 0.05 to 3.0 seconds

The overall Ni deposit in the roughened layer, the heat-resistant layer and the weathering layer was 683 μg/dm², based on the Zn deposit in the weathering layer and the rust-preventive layer, Zn/(Ni+Zn)=0.19, and based on the Co deposit in the roughened layer and the heat-resistant layer, Co/(Ni+Zn)=2.1. As a result of evaluating the infiltration, the infiltration width was favorable at 55 μm.

As a result of evaluating the adhesive strength, the normal peel strength was 0.90 kg/cm, and the sulfuric acid resistance degradation was 25 (Loss %), and the adhesive strength was satisfactory. No residual particles could be observed, and the alkali etchability was also favorable (∘).

The foregoing results are shown in Table 1. In addition, the overall Cr deposit was 89 μg/dm², the overall Co deposit was 1771 μg/dm², and the overall Zn deposit was 158 μg/dm².

### Example 4

The Ni deposit at the roughening stage was, as described above, 50 to 250 μg/dm². Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 6 to 11 A/dm²
Time: 0.05 to 3.0 seconds

### 2) Weatherable Layer (Zn—Ni Layer)

Current density (Dk): 1 to 3 A/dm²
Time: 0.05 to 3.0 seconds

### 3) Rust-Preventive Layer (Cr—Zn Layer)

Current density (Dk): 0.05 to 1.0 A/dm²
Time: 0.05 to 3.0 seconds

The overall Ni deposit in the roughened layer, the heat-resistant layer and the weathering layer was 758 μg/dm², based on the Zn deposit in the weathering layer and the rust-preventive layer, Zn/(Ni+Zn)=0.23, and based on the Co deposit in the roughened layer and the heat-resistant layer, Co/(Ni+Zn)=1.8. As a result of evaluating the infiltration, the infiltration width was extremely favorable at 0 μm.

As a result of evaluating the adhesive strength, the normal peel strength was 0.90 kg/cm, and the sulfuric acid resistance degradation was 22 (Loss %), and the adhesive strength was satisfactory. The alkali etchability was also favorable (∘).

The foregoing results are shown in Table 1. In addition, the overall Cr deposit was 90 μg/dm², the overall Co deposit was 1772 μg/dm², and the overall Zn deposit was 223 μg/dm².

### Example 5

The Ni deposit at the roughening stage was, as described above, 50 to 250 μg/dm². Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 7 to 12 A/dm²
Time: 0.05 to 3.0 seconds

### 2) Weatherable Layer (Zn—Ni Layer)

Current density (Dk): 0.6 to 1.5 A/dm²
Time: 0.05 to 3.0 seconds

### 3) Rust-Preventive Layer (Cr—Zn Layer)

Current density (Dk): 1.0 to 3.0 A/dm²
Time: 0.05 to 3.0 seconds

The overall Ni deposit in the roughened layer, the heat-resistant layer and the weathering layer was 815 μg/dm², based on the Zn deposit in the weathering layer and the rust-preventive layer, Zn/(Ni+Zn)=0.22, and based on the Co deposit in the roughened layer and the heat-resistant layer, Co/(Ni+Zn)=1.8. As a result of evaluating the infiltration, the infiltration width was extremely favorable at 0 μm.

As a result of evaluating the adhesive strength, the normal peel strength was 0.90 kg/cm, and the sulfuric acid resistance degradation was 12 (Loss %), and the adhesive strength was favorable. The alkali etchability was also favorable (∘).

The foregoing results are shown in Table 1. In addition, the overall Cr deposit was 115 μg/dm², the overall Co deposit was 1855 μg/dm², and the overall Zn deposit was 234 μg/dm².

### Example 6

Roughening treatment was performed to a rolled copper foil of 18 μm under the following conditions.

Liquid composition: Cu 10 to 20 g/liter, Co 5 to 10 g/liter, N±5 to 15 g/liter
pH: 2 to 4

### Temperature: 30 to 50° C.

Current density (Dk): 20 to 60 A/dm²
Time: 0.5 to 5 seconds

As a result of performing the roughening treatment under the foregoing conditions, formed was an assembly of fine roughened particles made from a ternary alloy of Cu, Co and Ni having an average particle size of 0.10 to 0.60 μm. The roughened particle size was evaluated by observing the roughened particles of the copper foil with the surface treated layers using a 30000× scanning electron microscope (SEM).

The Ni deposit at the roughening stage was 200 to 400 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 8 to 16 A/dm²
Time: 0.05 to 3.0 seconds

### 2) Weatherable Layer (Zn—Ni Layer)

Current density (Dk): 2.0 to 4.0 A/dm²
Time: 0.05 to 3.0 seconds

### 3) Rust-Preventive Layer (Cr—Zn Layer)

Current density (Dk): 0 A/dm²
Time: 0 seconds (immersion chromate treatment)

The overall Ni deposit in the roughened layer, the heat-resistant layer and the weathering layer was 1093 μg/dm², based on the Zn deposit in the weathering layer and the rust-preventive layer, Zn/(Ni+Zn)=0.18, and based on the Co deposit in the roughened layer and the heat-resistant layer, Co/(Ni+Zn)=1.9. As a result of evaluating the infiltration, the infiltration width was extremely favorable at 0 μm.

As a result of evaluating the adhesive strength, the normal peel strength was 0.88 kg/cm, and the sulfuric acid resistance degradation was ≦10 (Loss %) or less, and the adhesive strength was extremely favorable. The alkali etchability was also (∘).

The foregoing results are shown in Table 1. In addition, the overall Cr deposit was 110 μg/dm², the overall Co deposit was 2480 μg/dm², and the overall Zn deposit was 240 μg/dm².

### Example 7

Roughening treatment was performed to a rolled copper foil of 18 μm under the following conditions.

Liquid composition: Cu 10 to 20 g/liter, Co 5 to 10 g/liter, N±8 to 20 g/liter
pH: 2 to 4

### Temperature: 30 to 50° C.

Current density (Dk): 20 to 60 A/dm²
Time: 0.5 to 5 seconds

As a result of performing the roughening treatment under the foregoing conditions, formed was an assembly of fine roughened particles made from a ternary alloy of Cu, Co and Ni having an average particle size of 0.05 to 0.35 μm. The roughened particle size was evaluated by observing the roughened particles of the copper foil with the surface treated layers using a 30000× scanning electron microscope (SEM).

The Ni deposit at the roughening stage was 300 to 550 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 8 to 16 A/dm²
Time: 0.05 to 3.0 seconds

### 2) Weatherable Layer (Zn—Ni Layer)

Current density (Dk): 1.5 to 3.5 A/dm²
Time: 0.05 to 3.0 seconds

### 3) Rust-Preventive Layer (Cr—Zn Layer)

Current density (Dk): 0 A/dm²
Time: 0 seconds (immersion chromate treatment)

The overall Ni deposit in the roughened layer, the heat-resistant layer and the weathering layer was 790 μg/dm², based on the Zn deposit in the weathering layer and the rust-preventive layer, Zn/(Ni+Zn)=0.22, and based on the Co deposit in the roughened layer and the heat-resistant layer, Co/(Ni+Zn)=2.2. As a result of evaluating the infiltration, the infiltration width was extremely favorable at 0 μm.

As a result of evaluating the adhesive strength, the normal peel strength was 0.85 kg/cm, the sulfuric acid resistance degradation was 5.10 (Loss %) or less, and the adhesive strength was extremely favorable. The alkali etchability was also favorable (∘).

The foregoing results are shown in Table 1. In addition, the overall Cr deposit was 55 μg/dm², the overall Co deposit was 2170 μg/dm², and the overall Zn deposit was 217 μg/dm².

### Comparative Example 1

A roughened layer was formed on a roller copper foil of 18 μm under the same conditions as Examples 1 to 5. The Ni deposit at the roughening stage was 50 to 250 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 5 to 15 A/dm²
Time: 0.05 to 3.0 seconds

### 2) Weatherable Layer (Zn—Ni Layer)

Current density (Dk): 0.05 to 0.7 A/dm²
Time: 0.05 to 3.0 seconds

### 3) Rust-Preventive Layer (Cr—Zn Layer)

Current density (Dk): 0.5 to 1.5 A/dm²
Time: 0.05 to 3.0 seconds

The overall Ni deposit in the roughened layer, the heat-resistant layer and the weathering layer was 1197 μg/dm², based on the Zn deposit in the weathering layer and the rust-preventive layer, Zn/(Ni+Zn)=0.06, and based on the Co deposit in the roughened layer and the heat-resistant layer, Co/(Ni+Zn)=1.7. As a result of evaluating the infiltration, infiltration width was inferior at >5 μm.

As a result of evaluating the adhesive strength, the normal peel strength was 0.89 kg/cm, and the sulfuric acid resistance degradation was 510 (Loss %) or less, and the adhesive strength was favorable. Since residual particles were observed, the alkali etchability was inferior (x). Moreover, the comprehensive evaluation was inferior. The cause thereof is considered to be the total Ni deposit being excessive, and the Zn ratio being too small.

The foregoing results are shown in Table 1. In addition, the overall Cr deposit was 81 μg/dm², the overall Co deposit was 2188 μg/dm², and the overall Zn deposit was 82 μg/dm².

### Comparative Example 2

A roughened layer was formed on a roller copper foil of 18 μm under the same conditions as Examples 1 to 5. The Ni deposit at the roughening stage was 50 to 250 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 5 to 15 A/dm²
Time: 0.05 to 3.0 seconds

### 2) Weatherable Layer (Zn—Ni Layer)

Current density (Dk): 0.1 to 1.0 A/dm²
Time: 0.05 to 3.0 seconds

### 3) Rust-Preventive Layer (Cr—Zn Layer)

Current density (Dk): 0.5 to 1.5 A/dm²
Time: 0.05 to 3.0 seconds

The overall Ni deposit in the roughened layer, the heat-resistant layer and the weathering layer was 1237 μg/dm², based on the Zn deposit in the weathering layer and the rust-preventive layer, Zn/(Ni+Zn)=0.10, and based on the Co deposit in the roughened layer and the heat-resistant layer, Co/(Ni+Zn)=1.5. As a result of evaluating the infiltration, the infiltration width was favorable at ≦5 μm.

As a result of evaluating the adhesive strength, the normal peel strength was 0.90 kg/cm, and the sulfuric acid resistance degradation was 510 (Loss %) or less, and the adhesive strength was favorable. Nevertheless, since residual particles were observed, the alkali etchability was inferior (x). Moreover, the comprehensive evaluation was inferior. The cause thereof is considered to be the total Ni deposit being excessive.

The foregoing results are shown in Table 1. In addition, the overall Cr deposit was 84 μg/dm², the overall Co deposit was 2113 μg/dm², and the overall Zn deposit was 134 μg/dm².

### Comparative Example 3

A roughened layer was formed on a roller copper foil of 18 μm under the same conditions as Examples 1 to 5. The Ni deposit at the roughening stage was 50 to 250 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 3.0 to 7.0 A/dm²
Time: 0.05 to 3.0 seconds

### 2) Weatherable Layer (Zn—Ni Layer)

Current density (Dk): 0.05 to 0.7 A/dm²
Time: 0.05 to 3.0 seconds

### 3) Rust-Preventive Layer (Cr—Zn Layer)

Current density (Dk): 0.5 to 1.5 A/dm²
Time: 0.05 to 3.0 seconds

The overall Ni deposit in the roughened layer, the heat-resistant layer and the weathering layer was 311 μg/dm², based on the Zn deposit in the weathering layer and the rust-preventive layer, Zn/(Ni+Zn)=0.25, and based on the Co deposit in the roughened layer and the heat-resistant layer, Co/(Ni+Zn)=2.9. As a result of evaluating the infiltration, the infiltration width was favorable at ≦5 μm.

As a result of evaluating the adhesive strength, while the normal peel strength was favorable at 0.88 kg/cm, the sulfuric acid resistance degradation was inferior at 35 (Loss %). Since residual particles were observed, the alkali etchability was also inferior (x). The comprehensive evaluation was inferior. The cause thereof is considered to be the total Ni deposit being too low, and the Zn ratio being too great.

The foregoing results are shown in Table 1. In addition, the overall Cr deposit was 82 μg/dm², the overall Co deposit was 1204 μg/dm², and the overall Zn deposit was 101 μg/dm².

### Comparative Example 4

A roughened layer was formed on a roller copper foil of 18 μm under the same conditions as Examples 1 to 5. The Ni deposit at the roughening stage was 50 to 250 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 5.0 to 10 A/dm²
Time: 0.05 to 3.0 seconds

### 2) Weatherable Layer (Zn—Ni Layer)

Current density (Dk): 0.7 to 2.0 A/dm²
Time: 0.05 to 3.0 seconds

### 3) Rust-Preventive Layer (Cr—Zn Layer)

Current density (Dk): 0.8 to 2.5 A/dm²
Time: 0.05 to 3.0 seconds

The overall Ni deposit in the roughened layer, the heat-resistant layer and the weathering layer was 599 μg/dm², based on the Zn deposit in the weathering layer and the rust-preventive layer, Zn/(Ni Zn)=0.38, and based on the Co deposit in the roughened layer and the heat-resistant layer, Co/(Ni+Zn)=1.6. As a result of evaluating the infiltration, the infiltration width was favorable at 0 μm.

As a result of evaluating the adhesive strength, while the normal peel strength was favorable at 0.90 kg/cm, the sulfuric acid resistance degradation was inferior at 40 (Loss %). The alkali etchability was favorable (∘). However, the comprehensive evaluation was inferior. The cause thereof is considered to be the Zn ratio being too great.

The foregoing results are shown in Table 1. In addition, the overall Cr deposit was 122 μg/dm², the overall Co deposit was 1543 μg/dm², and the overall Zn deposit was 361 μg/dm².

### Comparative Example 5

A roughened layer was formed on a roller copper foil of 18 μm under the same conditions as Example 6. As a result of performing the roughening treatment under the foregoing conditions, formed was an assembly of fine roughened particles made from a ternary alloy of Cu, Co, and Ni having an average particle size of 0.10 to 0.60 μm.

The Ni deposit at the roughening stage was 200 to 400 μg/dm².

Formation of the heat resistance layer made from a Ni—Co layer, and the weathering layer and the rust-preventive layer which contain Zn, Ni and Cr, and the silane coupling treatment were implemented within the range of conditions described above. The conditions for forming the heat resistance layer, the weathering layer, and the rust-preventive layer are indicated below.

### 1) Heat-Resistant Layer (Ni—Co Layer)

Current density (Dk): 10 to 30 A/dm²
Time: 0.05 to 3.0 seconds

### 2) Weatherable Layer (Zn—Ni Layer)

Current density (Dk): 1.0 to 3.0 A/dm²
Time: 0.05 to 3.0 seconds

### 3) Rust-Preventive Layer (Cr—Zn Layer)

Current density (Dk): 0 A/dm²
Time: 0 seconds (immersion chromate treatment)

The overall Ni deposit in the roughened layer, the heat-resistant layer and the weathering layer was 816 μg/dm², based on the Zn deposit in the weathering layer and the rust-preventive layer, Zn/(Ni+Zn)=0.13, and based on the Co deposit in the roughened layer and the heat-resistant layer, Co/(Ni+Zn)=3.2. As a result of evaluating the infiltration, the infiltration width was inferior at >5 μm.

As a result of evaluating the adhesive strength, the normal peel strength was 0.90 kg/cm, and the sulfuric acid resistance degradation was 510 (Loss %), and the adhesive strength was favorable. The alkali etchability was also favorable (∘). However, the comprehensive evaluation was inferior. The cause thereof is considered to be the total Co deposit being excessive.

The foregoing results are shown in Table 1. In addition, the overall Cr deposit was 90 μg/dm², the overall Co deposit was 2987 μg/dm², and the overall Zn deposit was 119 μg/dm².

### INDUSTRIAL APPLICABILITY

In a copper clad laminate which uses a copper foil for a printed circuit obtained by performing roughening treatment on a surface of a copper foil and then forming a heat-resistant layer and a rust-preventive layer thereon, and to which silane coupling treatment is subsequently performed, the copper foil for a printed circuit of the present invention can further inhibit the deterioration in adhesion caused by the acid infiltration into the interface of the copper foil circuit and the substrate resin upon performing acid treatment or chemical etching to the substrate after forming a fine-pattern printed circuit, and yield superior acid-resistant adhesive strength and superior alkali etchability. Consequently, while the downsizing and higher integration of semiconductor devices are further advancing and even stricter demands are being made to the production process of the printed circuits thereof in the course of further advancement of electronic devices, the present invention can provide useful technology that can meet the foregoing demands.

1. A copper foil with surface treated layers, comprising:
a copper foil or a copper alloy foil having a plurality of surface treated layers including a roughened layer formed on the copper foil or the copper alloy foil by roughening treatment, a heat-resistant layer made from a Ni—Co layer formed on the roughened layer; and a weathering layer and a rust-preventive layer containing Zn, Ni, and Cr formed on the heat-resistant layer; and
the plurality of surface treated layers having a total Zn/(total Zn+total Ni) ratio of 0.13 or more and 0.23 or less and a total Co content of 2500 μg/dm² or less.

2. The copper foil with surface treated layers according to claim 1, wherein a total Ni content in the surface treated layers is 450 to 1100 μg/dm².

3. The copper foil with surface treated layers according to claim 1, wherein a total Co content in the surface treated layers is 770 μg/dm² or more, and a total Co/(total Zn+total Ni) ratio is 3.0 or less.

4. The copper foil with surface treated layers according to claim 1, wherein a total Cr content in the surface treated layers is 50 to 130 μg/dm².

5. The copper foil with surface treated layers according to claim 1, wherein a Ni content in the roughened layer is 50 to 550 μg/dm².

6. The copper foil with surface treated layers according to claim 1, wherein the roughened layer is made of Co, Cu, and Ni.

7. The copper foil with surface treated layers according to claim 1, wherein the roughened layer is made from fine particles of a ternary alloy of Cu, Co, and Ni having an average particle size of 0.05 to 0.60 μm.

8. The copper foil with surface treated layers, according to claim 1, wherein the roughened layer is configured from a primary particle layer made of Cu having an average particle size of 0.25 to 0.45 μm and a secondary particle layer made from a ternary alloy of Cu, Co, and Ni having an average particle size of 0.05 to 0.25 μm formed on the primary particle layer.

9. A copper foil for a printed circuit made from the copper foil with surface treated layers according to claim 1.

10. A copper clad laminate comprising the copper foil for a printed circuit according to claim 9 bonded to a resin substrate.

11. A copper foil with surface treated layers, comprising:
a copper foil or a copper alloy foil having a plurality of surface treated layers including a roughened layer formed on the copper foil or the copper alloy foil by roughening treatment, a heat-resistant layer made from a Ni—Co layer formed on the roughened layer, and a weathering layer and a rust-preventive layer containing Zn, Ni, and Cr formed on the heat-resistant layer;
the plurality of surface treated layers having a total Zn/(total Zn+total Ni) ratio of 0.13 or more and 0.23 or less; and
the roughened layer being configured from a primary particle layer made of Cu having an average particle size of 0.25 to 0.45 μm and a secondary particle layer made from a ternary alloy of Cu, Co, and Ni having an average particle size of 0.05 to 0.25 μm formed on the primary particle layer.

12. The copper foil with surface treated layers according to claim 11, wherein a total Co content in the surface treated layers is 770 to 2500 μg/dm², and a total Co/(total Zn+total Ni) ratio is 3.0 or less.

13. The copper foil with surface treated layers according to claim 12, wherein a total Ni content in the surface treated layers is 450 to 1100 μg/dm².

14. The copper foil with surface treated layers according to claim 13, wherein a total Cr content in the surface treated layers is 50 to 130 μg/dm².

15. The copper foil with surface treated layers according to claim 14, wherein a Ni content in the roughened layer is 50 to 550 μg/dm².

16. The copper foil according to claim 15, wherein the copper foil is bonded to a resin substrate.

17. The copper foil with surface treated layers according to claim 11, wherein a total Ni content in the surface treated layers is 450 to 1100 μg/dm².

18. The copper foil with surface treated layers according to claim 11, wherein a total Cr content in the surface treated layers is 50 to 130 μg/dm².

19. The copper foil with surface treated layers according to claim 11, wherein a Ni content in the roughened layer is 50 to 550 μg/dm².

20. The copper foil according to claim 11, wherein the copper foil is bonded to a resin substrate.
